(19) United States
(12) Patent Application Publication
(10) Pub. No.: US 2021/0165264 A1
(43) Pub. Date: Jun. 3, 2021

(54) Display Module and Display Device

(71) Applicants: K-Tronics (Suzhou) Technology Co., Ltd., Jiangsu (CN); BOE Technology Group Co., Ltd., Beijing (CN)

(72) Inventor: Chihchung Wang, Beijing (CN)

(21) Appl. No.: 16/963,279

(22) PCT Filed: Dec. 25, 2019
(86) PCT No.: PCT/CN2019/128342

§ 371 Date: Jul. 20, 2020

(30) Foreign Application Priority Data
Jan. 18, 2019 (CN) 201920090656.5

(51) Int. Cl. G02F 1/1345; G02F 1/1339; H05K 1/02

(52) U.S. Cl. CPC G02F 1/13452; H05K 2201/10136; H05K 1/028; G02F 1/1339

(57) ABSTRACT

A display module is provided in embodiments of the present disclosure, including: a display panel; a printed circuit board electrically connected to the display panel; a sealant frame on at least one side edge of the display panel; and a plurality of flexible circuit boards electrically connected to the printed circuit board; wherein the printed circuit board is located on a side of the display panel facing away from a light exit side of the display panel; the plurality of flexible circuit boards are located outside a sidewall of the display panel and are arranged along a first side edge of the display panel, and the plurality of flexible circuit boards comprise respective bent portions beyond the sealant frame and electrically connected to the printed circuit board and the display panel; and at least a part of the sealant frame close to the first side edge extends laterally in a direction facing away from the display panel and protrudes from the bent portions. A display device is also provided in embodiments of the disclosure.

### CROSS-REFERENCE TO RELEVANT APPLICATION

The embodiments of the present disclosure claims the benefit of Chinese Patent Application with the application number 201920090656.5 filed on Jan. 18, 2019 with China Intellectual Property Office, the whole disclosure of which is incorporated herein by reference.

### TECHNICAL FIELD

Embodiments of the present disclosure relate to the field of display technology, and in particular, to a display module and a display device.

### BACKGROUND

With a development of display devices, requirements on display devices become progressively higher. On the market, liquid crystal display devices are more common. Among others, a liquid crystal display device comprises a backlight module and a liquid crystal display panel. Generally, it is required that the liquid crystal display panel is to be connected with printed circuit board(s) through flexible circuit board(s), such that the liquid crystal display device operates normally.

According to differences in positions of printed circuit boards, the structures of liquid crystal display devices may be divided into a flat type structure and a bend type structure. In a liquid crystal display device of the bend type structure, respective printed circuit board(s) may be provided at the bottom of a display in the liquid crystal display device, and may be connected with the display (especially the liquid crystal display panel of the liquid crystal display device) through respective flexible circuit board. A sealant frame structure is also used in the liquid crystal display device to protect components of the display. However, the flexible circuit board in the liquid crystal display device of the bend type structure extends beyond the sealant frame structure, i.e., a portion of the flexible circuit board that extends beyond the sealant frame is not protected by the sealant frame.

In addition, it is usually necessary to wrap an insulating protective layer (for example, wrapping an insulating tape) on an outermost side of the sealant frame so as to improve overall protective properties of the liquid crystal display device. However, the insulating protective layer can merely provide basic protection against scratches, rather than providing protection against damage that may be caused by interference with the flexible circuit board during an assembling process.

### SUMMARY

The embodiments of the present disclosure have been made to overcome or alleviate at least one aspect of the above mentioned defects and/or deficiencies in the relevant art, by providing a display module and a display device.

Following technical solutions are mainly provided in exemplary embodiments of the disclosure.

For solving above problems, in a first aspect of embodiments of the present disclosure, there is provided a display module, comprising: a display panel; a printed circuit board electrically connected to the display panel; a sealant frame on at least one side edge of the display panel; and a plurality of flexible circuit boards electrically connected to the printed circuit board; wherein the printed circuit board is located on a side of the display panel facing away from a light exit side of the display panel; the plurality of flexible circuit boards are located outside a sidewall of the display panel and are arranged along a first side edge of the display panel, and the plurality of flexible circuit boards comprise respective bent portions beyond the sealant frame and electrically connected to the printed circuit board and the display panel; and at least a part of the sealant frame close to the first side edge extends laterally in a direction facing away from the display panel and protrudes from the bent portions.

In accordance with embodiments of the present disclosure, the sealant frame is arranged to surround all side edges of the display panel.

In accordance with embodiments of the present disclosure, opening are provided at locations of portions of the sealant frame on a side of the plurality of flexible circuit board corresponding to the bent portions, and the bent portions extend through the openings respectively.

In accordance with embodiments of the present disclosure, the sealant frame comprises: a first sealant frame arranged to surround all side edges of the display panel; and a second sealant frame extending in a direction perpendicular to the first side edge and facing away from the display panel, and the bent portions are arranged to be electrically connected to the printed circuit board through the openings and to bypass the first sealant frame.

In accordance with embodiments of the present disclosure, along a direction of the first side edge, the second sealant frame is provided on at least one lateral side of each bent portion, with a non-zero gap existing between the bent portions and the second sealant frame and being greater than or equal to a first preset distance.

In accordance with embodiments of the present disclosure, along the direction of the first side edge, the second sealant frame is provided on both lateral sides of each bent portion, with a non-zero first gap existing between the bent portion and a portion of the second sealant frame at one lateral side of the bent portion and being greater than or equal to the first preset distance, and also with a second gap exiting between the bent portion and a portion of the second sealant frame at the other lateral side of the bent portion and being greater than or equal to a second preset distance.

In accordance with embodiments of the present disclosure, the first preset distance is equal to the second preset distance.

In accordance with embodiments of the present disclosure, along the direction perpendicular to the first side edge, a length of the second sealant frame is greater than a length of the first sealant frame.

In accordance with embodiments of the present disclosure, the second sealant frame further comprises an extension portion, and the printed circuit board is formed with a recessed portion; and the extension portion is arranged in a direction perpendicular to the first sealant frame and is connected to the second sealant frame, and the positions of the extension portion and the recessed portion are directly opposite to each other, and the extension portion are sized and shaped for being inserting into the recessed portion.

In accordance with embodiments of the present disclosure, a material of the extension portion is the same as a material of the sealant frame, and the extension portion is integrally formed with the sealant frame.

In accordance with embodiments of the present disclosure, the display module further comprises a backlight module provided adjacent to the display panel.

In a second aspect of embodiments of the present disclosure, there is provided a display device comprising the display module of the first aspect.

Additional aspects and advantages of the embodiments of the disclosure are provided in the following depictions, and will become apparent from the latter or be acknowledged by implementation of embodiments of the disclosure.

### BRIEF DESCRIPTION OF THE DRAWINGS

In order to explain technical solutions of the embodiments of the present disclosure more clearly, the drawings of the embodiments will be briefly described below. It should be understood that the drawings described below merely relate to some embodiments of the present disclosure, rather than restricting the present disclosure, in which:

FIG. 1 is a right side view of a display module having a flat type structure in relevant art;

FIG. 2 is a right side view of a display module having a bend type structure in relevant art;

FIG. 3 is a front view of a first example of a display module having the bend type structure in relevant art;

FIG. 4 is a bottom view of the first example of the display module having the bend type structure in relevant art;

FIG. 5 is a right side view of a display module according to a first embodiment in embodiments of the present disclosure;

FIG. 6 is a front view of the display module according to the first embodiment in embodiments of the present disclosure;

FIG. 7 is a bottom view of the display module according to the first embodiment in embodiments of the present disclosure;

FIG. 8 is a front view of the display module which is optimized according to the first embodiment in embodiments of the present disclosure;

FIG. 9 is a rear view of the display module according to the first embodiment in embodiments of the present disclosure;

FIG. 10 is a schematic structural diagram of a second sealant frame, an extension portion, and a recessed portion according to embodiments of the present disclosure;

FIG. 11 is a bottom view of a display module having the bend type structure in relevant art, according to a second embodiment in embodiments of the present disclosure;

FIG. 12 is a bottom view of the display module according to the second embodiment in embodiments of the present disclosure.

### DETAILED DESCRIPTION OF EMBODIMENTS

In order to more clearly explain the purposes, technical solutions and advantages of the present disclosure, the embodiments of the present disclosure will be described in detail below with reference to the drawings. It should be understood that the following description of the embodiments is intended to explain and elaborate the general concept of the present disclosure, and should not be construed as limiting the present disclosure. In the description and the drawings, the same or similar reference numerals refer to the same or similar parts or components. For clarity, the drawings are not necessarily drawn to scale, and some well-known components and structures may be omitted in the drawings.

Those skilled in the art can understand that unless specifically stated, the singular forms “a”, “an”, “said” and “the” used herein may also comprise the plural forms. It should be further understood that the word “comprising” used in the description of the embodiments of the present disclosure refers to the presence of the described features, integers, steps, operations, elements and/or components, but does not exclude the presence or addition of one or more other features, integers, steps, operations, elements, components, and/or groups thereof. It should be understood that when an element is referred to as being “connected” to another element, it can be directly connected to the other element, or intervening elements may also be present. The word “and/or” used herein comprises all or any unit and all combinations of one or more associated listed items.

Those skilled in the art can understand that unless otherwise defined, all terms (comprising technical and scientific terms) used herein have the same meaning as those generally understood by those of ordinary skill in the art to which the embodiments of the present disclosure belong. It should also be understood that terms such as those defined in a general dictionary should be understood to have a meaning consistent with the meaning in the context of relevant technologies, and unless specifically defined as here, would not be explained with idealized or overly formal.

The shapes and sizes of the components in the drawings do not reflect the true proportions of the various layers and components of the display module and the display device provided by the embodiments of the present disclosure, and the purpose is only to schematically illustrate the contents of the embodiments of the present disclosure.

FIG. 1 shows a right side view of a display module having a flat type structure in relevant art. As shown in FIG. 1, the display module comprises: a backlight module 1, a back plate 3 disposed above the backlight module 1 in a direction facing away from the backlight module 1, a display panel 2, a sealant frame 6, a flexible circuit board 4 extending from a sidewall of the display panel 2 outwardly beyond the sealant frame 6, and a printed circuit board 5 located laterally outside the display panel 2 and electrically connected to the flexible circuit board 4, the printed circuit board 5 being located even more outwardly from the display panel 2 than the flexible circuit board 4 in the lateral direction; and, the display panel 2 more specifically comprises an array substrate 21 and a color filter substrate 22 that are oppositely disposed, wherein the array substrate 21 is closer to the backlight module 1 than the color filter substrate 22. The flexible circuit board 4 is arranged in a direction parallel to the sidewall of the display panel 2 and extends laterally beyond the display panel 2, wherein one end of the flexible circuit board 4 is connected to the array substrate 21, and the other end of the flexible circuit board 4 is connected to the printed circuit board 5. The sealant frame 6 surrounds at least one side edge of the backlight module 1, and the sealant frame 6 further tightly surrounds the display panel 2 as shown in the figure, for example, to protect the display module. Since the flexible circuit board 4 in this condition extends beyond the sealant frame 6, rather than being located at the outermost of the entire display module, then, subsequent assembly processes may have little effect on the flexible circuit board 4.

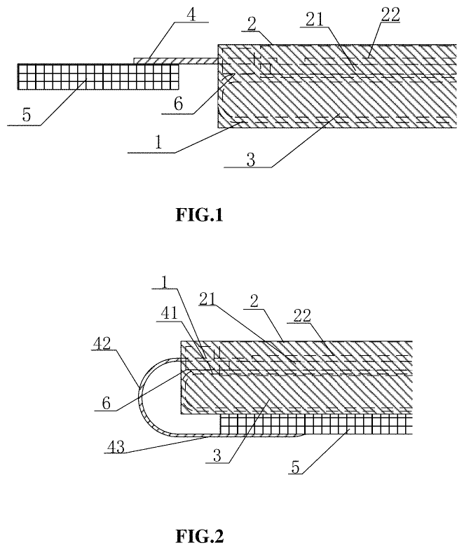

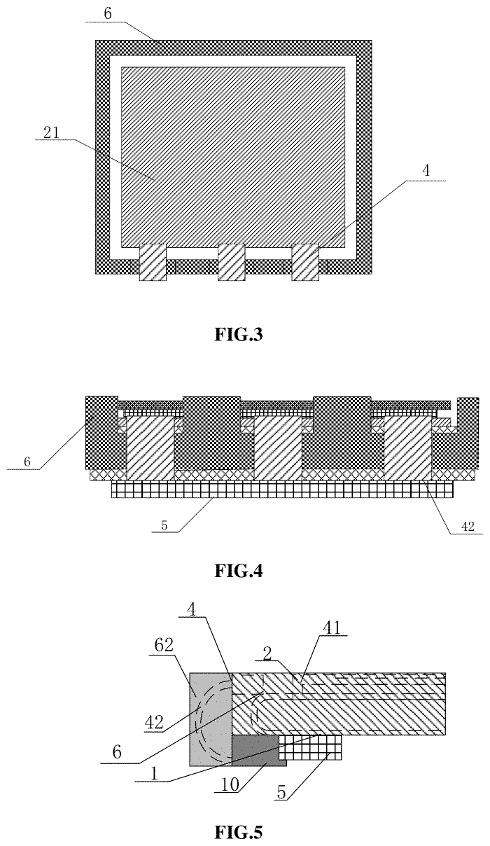

FIG. 2 and FIG. 3 respectively show a right side view and a front view of a display module having a bend type structure in relevant art. As shown in FIG. 2 and FIG. 3, the structure of the display module is similar to the structure of the display module shown in FIG. 1, except that the printed circuit board 5 is located on the side of the display panel facing away from its light exit side (that is, opposite to the light exit side), rather than being located laterally outside the display panel as shown in FIG. 1. In this condition, the flexible circuit board 4 needs to be bent above all such that it can in turn be connected to the printed circuit board 5, and the flexible circuit board 4 comprises a first horizontal portion 41 and a second horizontal portion 42 arranged parallel to each other, and a bent portion 43 therebetween. The first horizontal portion 41 is connected to the array substrate 21, and the second horizontal portion 43 is connected to the printed circuit board 5. Therefore, as opposed to a condition where the printed circuit board 5 in the display module of the flat type structure in relevant art as illustrated in FIG. 1 is located laterally even more outwardly from the display panel 2 than the flexible circuit board 4, in the display module having the bend type structure in the relevant art as illustrated in FIG. 2 and FIG. 3, the flexible circuit board 4 is located laterally even more outwardly from the display panel 2 than the printed circuit board 5. Moreover, considering that the sealant frame 6 further tightly surround the display panel 2 as shown in the figure, for example, the bent portion 42 in this structure is located laterally at the outermost of the display module and is not protected (especially not protected by sealant frame 6), so it is easy to damage the bent portion 42 during the subsequent assembly processes.

Specifically, FIG. 3 and FIG. 4 respectively show a bottom view and a front view of the first embodiment of the display module having the relevant bend type structure. As shown in FIG. 3 and FIG. 4, in comparison with the display module having the flat type structure, since as opposed to a condition where the printed circuit board 5 in the display module of the flat type structure in relevant art as illustrated in FIG. 1 is located laterally even more outwardly from the display panel 2 than the flexible circuit board 4, in the display module having the bend type structure in the relevant art as illustrated in FIG. 2 and FIG. 3, the flexible circuit board 4 is located laterally even more outwardly from the display panel 2 than the printed circuit board 5, then, a lateral size of the display module having the bend type structure is smaller, resulting in a smaller volume thereof, as compared with the display module having the flat type structure. However, in a condition that an external side of the display module having the bend type structure is wrapped with an insulating tape, for example, since the sealant frame 6 fails to completely cover the flexible circuit board 4 along a cross-sectional direction in FIG. 2, that is, the sealant frame 6 cannot completely cover the bent portion 42 of the flexible circuit board 4, such that when the insulating tape is being disposed or provided, a part of the insulating tape may contact the flexible circuit board 4, which directly causes damage to the flexible circuit board 4 and impairs the display effect of the display module.

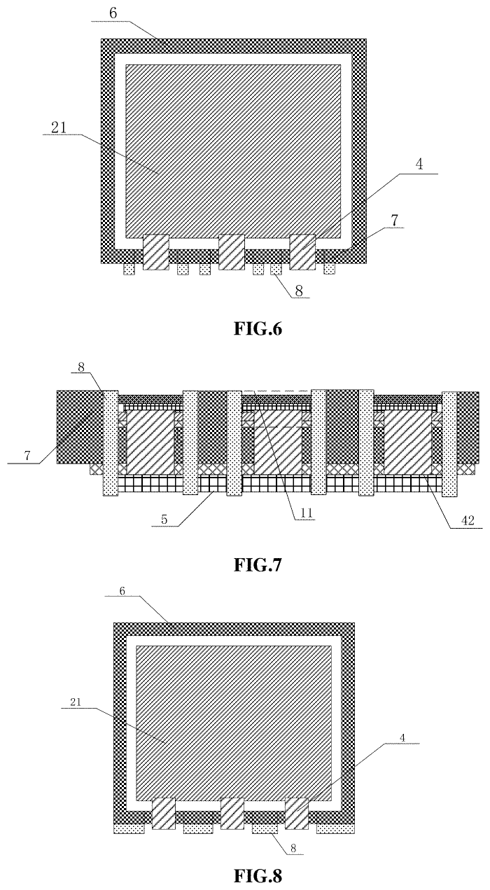

According to a general technical concept of the embodiments of the present disclosure, it is intended to provide a display module and a display device in the embodiments of the present disclosure. In order to solve technical problems existing in the first embodiment of the display module having the relevant bend type structure, then, a display module is provided in a first aspect of embodiments of the present disclosure, and FIG. 5 to FIG. 7 show the display module according to a first embodiment in embodiments of the present disclosure. As illustrated in FIG. 5 to FIG. 7, a display module comprises: a display panel 2; a printed circuit board 5 electrically connected to the display panel (for example, electrically connected to an array substrate of the display panel); a sealant frame 6 provided on at least one side edge of the display panel; and a plurality of flexible circuit boards 4 electrically connected to the printed circuit board. The printed circuit board 5 is located on a side of the display panel 2 facing away from a light exit side of the display panel (namely, a side opposite to the light exit side); the plurality of flexible circuit boards 4 are located outside a sidewall of the display panel 2, and the plurality of flexible circuit boards 4 comprise respective bent portions 42 (each flexible circuit board comprise a respective one bent portion 42) beyond the sealant frame 6 and electrically connected to the printed circuit board 5 and the display panel 2. Specific arrangement of the display panel 2, the plurality of flexible circuit boards 4, the printed circuit board 5 and the sealant frame 6 are similar to the arrangement of those in the display module having a bend type structure in relevant art, especially those as illustrated in FIG. 2 to FIG. 4 (more especially that in FIG. 2), and will not be repeated here. In addition, it should be noted that, as shown in the figure, the display module further comprises a backlight module 1 provided adjacent to the display panel 2, and the printed circuit board 5 in this embodiment may be adhered via conductive foam and adhesive, for example, to the backlight module 1, or it is fixed to a holder (not illustrated) in a back plate 3 which is provided to abut against the backlight module 1, in a way of film covering or the like.

The plurality of flexible circuit boards 4 are arranged along a side edge of the display panel 2 (for example, a left side edge as illustrated, hereinafter referred to as a first side edge), and the sealant frame 6 is arranged, for example, as illustrated, to closely surround all side edges of the display panel 2, at least a part of the sealant frame 6 close to the first side edge of the display panel 2 extends laterally in a direction facing away from the display panel 2 and protrudes from and beyond the bent portion 42.

Since in the embodiments of the present application at least a part of the sealant frame close to the first side edge of the display panel 2 extends laterally in a direction facing away from the display panel and protrudes from and beyond the bent portion, then, a thickness of a part of the sealant frame close to the bent portion is greater than a distance between an edge of the bent portion laterally facing away from an edge of a display area and the sidewall of the display panel, such that under the protection of the sealant frame, the flexible circuit boards may not become an outermost component, reducing a risk of directly or indirectly causing damage to the flexible circuit boards during assembly, and improving an overall protectiveness (i.e., protective property) of the display module, facilitating improving the display effect of the display module.

And, specifically, according to embodiments of the present disclosure, FIG. 7 shows a bottom view of the display module according to the first embodiment in embodiments of the present disclosure. As shown in FIG. 7, openings 11 are provided at respective locations of portions of the sealant frame 6 on a side of the plurality of flexible circuit board 4 corresponding to the bent portions 42 (such a side is illustrated as the upper side), and the bent portions 42 extend through the openings 11 respectively, such that the plurality of flexible circuit boards 4 may bypass the sealant frame 6. The expression “corresponding to” here means, for example, a relationship such as: adjacent to, or abutting against, or in an assembly relationship.

In addition, specifically, the sealant frame 6 provided along the first side edge of the display panel 2 comprises a first sealant frame 7 and a second sealant frame 8. The first sealant frame 7 is, for example as illustrated, arranged to tightly surround all side edges of the display panel 2; and the second sealant frame 8 extends in a direction perpendicular to the display panel 2 shown in FIG. 5 and is arranged orthogonally to the first sealant frame 7 on at least one lateral side of the first sealant frame 7 (and specifically extends in a direction facing away from the display panel 2, namely, the second sealant frame 8 extends in a direction perpendicular to the first side edge and facing away from the display panel 2) so as to form the openings 11 which are defined between the first sealant frame 7 and the second sealant frame 8 and are concave inwards the display module. The bent portions 42 are electrically connected to the printed circuit board 5 by passing through the opening 11 and bypassing the first sealant frame 7. In such an embodiment, the second sealant frame 8 is provided on both lateral sides of the openings 11, such that the sealant frame can protect the bent portions 42 from both lateral sides thereof, so as to provide a comprehensive protection for the bent portions 42.

According to embodiments of the present disclosure, along the direction of the first side edge of the display panel 2, the second sealant frame 8 is provided on at least one lateral side of each bent portion, with a non-zero gap existing between the bent portions 42 and the second sealant frame 8 and being greater than or equal to a first preset distance (the first preset distance functions as a set threshold), so as to ensure that the second sealant frame 8 does not contact the bent portions 42 of the flexible circuit boards 4.

According to the embodiments of the present disclosure, along the direction of the first side edge of the display panel 2, the second sealant frame 8 is provided on both lateral sides of each bent portion 42, with a non-zero first gap existing between the bent portion 42 and a portion of the second sealant frame 8 at one lateral side of the bent portion 42 and being greater than or equal to the first preset distance, and also with a non-zero second gap exiting between the bent portion 42 and a portion of the second sealant frame 8 at the other lateral side of the bent portion 42 and being greater than or equal to a second preset distance. In one embodiment, the first preset distance is equal to the second preset distance. However, for those skilled in the art, the first preset distance may not be equal to the second preset distance.

It should be noted that, the preset distance (i.e., the first preset distance, and the second preset distance) as mentioned in the embodiments of the present invention are determined depending on the actual size of the display panel and specific size and number of the plurality of flexible circuit boards 4. Depending on requirements of different display panels, specific shape of the sealant frame may not be limited to the embodiments of the present disclosure. In addition, in order to prevent the second sealant frame 8 from contacting the plurality of flexible circuit boards 4 and causing unnecessary damage, the gaps in the embodiments of the present disclosure should be greater than zero.

According to embodiments of the present disclosure, in the direction perpendicular to the first side edge of the display panel 2, the length of the second sealant frame 8 is greater than the length of the first sealant frame 7. In such an embodiment, similar to the display module of previous embodiments, in the direction perpendicular to the first side edge, the second sealant frame 8 extends until it abuts against the printed circuit board 5. In this embodiment, in the case where the second sealant frame 8 extends to the printed circuit board 5, the second sealant frame 8 may not only protect the bent portions 42 but also protect the second horizontal portion 43 connected to the printed circuit board 5, further enhancing the protectiveness of flexible circuit board 4 by the sealant frame 6.

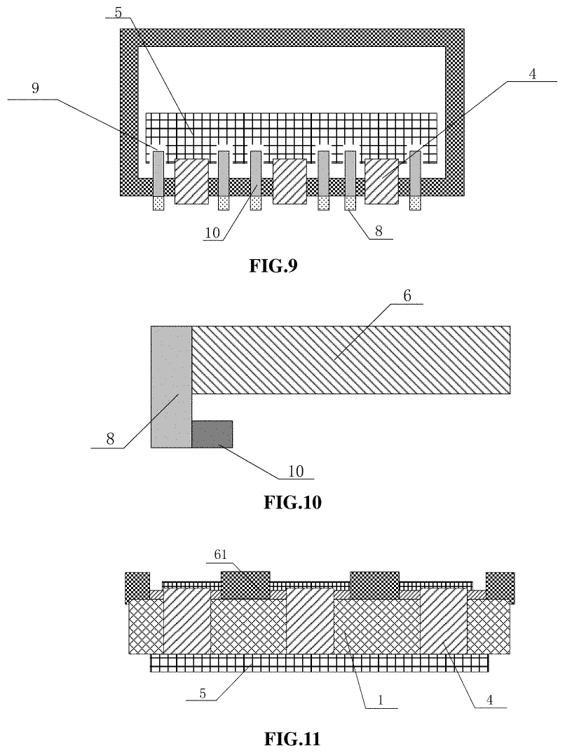

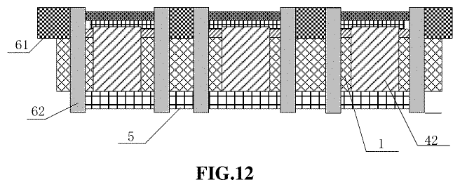

In order to assist in positioning the printed circuit board and to reduce the manufacturing steps and costs of the display module, as shown in FIGS. 9 and 10, taking the display module of the second embodiment as an example, the printed circuit board 5 is also formed with a recessed portion 9; meanwhile the display module according to the embodiments of the present application further comprises an extension portion 10, and the extension portion 10 is arranged in a direction perpendicular to the second sealant frame 8 and is connected to the second sealant frame 8. After the connection is completed, in the cross sectional view, the connection is in the form of an L shape; as shown in FIG. 12, the positions of the extension portion 10 and the recessed portion 9 are directly opposite to each other, and the extension portion 10 are sized and shaped to be suitable for insertion into the recessed portion 9; thus, provision of the extension portion 10 can well assist in positioning the printed circuit board.

According to an embodiment of the present disclosure, a material of the extension portion 10 is selected to be the same as a material of the second sealant frame 8, for example, and the extension portion 10 is integrally formed with the second sealant frame 8. Since the second sealant frame 8 and the extension portion 10 are formed by one and the same material, the cost of material selection can be saved. Furthermore, since the extension portion 10 and the second sealant frame 8 are integrally formed, the production time can be saved and the production cost can be reduced.

In another alternative embodiment, as shown in FIGS. 11 and 12, the sealant frame 6 provided on one side of the flexible circuit board 4 comprises a plurality of first rod portions 61 extending parallel to the first side edge and a plurality of second rod portions 62 extending in a direction perpendicular to the first side edge, and the plurality of second rod portions 62 are provided at least on one end of the plurality of first rod portions 61, respectively.

According to an embodiment of the present disclosure, the plurality of second rod portions 62 extend to the printed circuit board 5 in the direction perpendicular to the first side edge. In this embodiment, in the case where the plurality of second rod portions 62 extend to the printed circuit board 5, the plurality of second rod portions 62 can protect not only the bent portion 42 but also the second horizontal portion 43, further enhancing the protectiveness of the flexible circuit board 4 by the sealant frame 6.

Based on the same inventive concept, in a second aspect of the embodiments of the present disclosure, there is also provided a display device comprising the display module of the first aspect.

The beneficial effects of the display device in the second aspect will not be repeated here, since they are similar to the beneficial effects of the display module in the first aspect.

The beneficial effects obtained by applying the embodiments of the present disclosure comprise the followings.

Since in the embodiments of the present application at least a part of the sealant frame close to the first side edge of the display panel 2 extends laterally in a direction facing away from the display panel and protrudes from and beyond the bent portion, then, a thickness of a part of the sealant frame close to the bent portion is greater than a distance between an edge of the bent portion laterally facing away from an edge of a display area and the sidewall of the display panel, such that under the protection of the sealant frame, the flexible circuit boards may not become an outermost component, reducing a risk of directly or indirectly causing damage to the flexible circuit boards during assembly, and improving an overall protectiveness (i.e., protective property) of the display module, facilitating improving the display effect of the display module.

Although the present disclosure has been described with reference to the drawings, the embodiments disclosed in the drawings are intended to illustrate the embodiments of the present disclosure, and should not be construed as a limitation of the present disclosure. Dimensions and proportions in the drawings are merely schematic and should not be construed as limiting the present disclosure.

The above-mentioned embodiments only exemplarily illustrate the principle and structure of embodiments of the present disclosure, and are not intended to limit the present disclosure. It should be understood by those skilled in the art that, any changes and improvements made to the present disclosure fall within the scope of the present disclosure, without departing from the general concept of the present disclosure. The protection scope of the present disclosure shall be as defined in the claims of this application.

1. A display module, comprising:
a display panel;
a printed circuit board electrically connected to the display panel;
a sealant frame on at least one side edge of the display panel; and
a plurality of flexible circuit boards electrically connected to the printed circuit board,
wherein
the printed circuit board is located on a side of the display panel facing away from a light exit side of the display panel;
the plurality of flexible circuit boards are located outside a sidewall of the display panel and are arranged along a first side edge of the display panel, and the plurality of flexible circuit boards comprise respective bent portions beyond the sealant frame and electrically connected to the printed circuit board and the display panel; and
at least a part of the sealant frame close to the first side edge extends laterally in a direction facing away from the display panel and protrudes from the bent portions.

2. The display module according to claim 1, wherein the sealant frame is arranged to surround all side edges of the display panel.

3. The display module according to claim 1, wherein opening are provided at locations of portions of the sealant frame on a side of the plurality of flexible circuit board corresponding to the bent portions, and the bent portions extend through the openings respectively.

4. The display module according to claim 3, wherein
the sealant frame comprises:
a first sealant frame arranged to surround all side edges of the display panel; and
a second sealant frame extending in a direction perpendicular to the first side edge and facing away from the display panel, and
the bent portions are arranged to be electrically connected to the printed circuit board through the openings and to bypass the first sealant frame.

5. The display module according to claim 4, wherein along a direction of the first side edge, the second sealant frame is provided on at least one lateral side of each bent portion, with a non-zero gap existing between the bent portions and the second sealant frame and being greater than or equal to a first preset distance.

6. The display module according to claim 5, wherein along the direction of the first side edge, the second sealant frame is provided on both lateral sides of each bent portion, with a non-zero first gap existing between the bent portion and a portion of the second sealant frame at one lateral side of the bent portion and being greater than or equal to the first preset distance, and also with a second gap exiting between the bent portion and a portion of the second sealant frame at the other lateral side of the bent portion and being greater than or equal to a second preset distance.

7. The display module according to claim 6, wherein the first preset distance is equal to the second preset distance.

8. The display module according to claim 4, wherein along the direction perpendicular to the first side edge, a length of the second sealant frame is greater than a length of the first sealant frame.

9. The display module according to claim 8, wherein the second sealant frame further comprises an extension portion, and the printed circuit board is formed with a recessed portion; and
the extension portion is arranged in a direction perpendicular to the first sealant frame and is connected to the second sealant frame, and the positions of the extension portion and the recessed portion are directly opposite to each other, and the extension portion are sized and shaped for being inserting into the recessed portion.

10. The display module according to claim 1, wherein a material of the extension portion is the same as a material of the sealant frame, and the extension portion is integrally formed with the sealant frame.

11. The display module according to claim 1, wherein the display module further comprises a backlight module provided adjacent to the display panel.

12. A display device comprising the display module according to claim 1.
